(19) United States
(12) Patent Application Publication
(10) Pub. No.: US 2010/0132983 A1
(43) Pub. Date: Jun. 3, 2010

(54) RIGID PRINTED CIRCUIT BOARD, PCB ASSEMBLY, AND PCB MODULE HAVING SAME

(75) Inventors: Kai-Chi Lin, Chu-Nan (TW); Hsiu-Ping Chang, Chu-Nan (TW); Chih-Ming Lai, Chu-Nan (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXSEMICON INTEGRATED TECHNOLOGY, INC., Chu-Nan (TW)

(21) Appl. No.: 12/541,359

(22) Filed: Aug. 14, 2009

(30) Foreign Application Priority Data
Dec. 2, 2008 (CN) 200810305922.8

(51) Int. Cl. H05K 1/02

(52) U.S. Cl. 174/255

(57) ABSTRACT

An exemplary rigid printed circuit board (PCB) includes a main portion, a supporting portion and a connecting portion. The supporting portion is for supporting electrical elements. The connecting portion includes two end portions and a main body therebetween. The main body is spaced from the main portion and the supporting portion. The two end portions are respectively connected to the main portion and the supporting portion. A PCB assembly and a PCB module using the same are also provided.

### BACKGROUND

1. Technical Field

The present disclosure generally relates to printed circuit boards, particularly, to a rigid printed circuit board.

2. Description of Related Art

Nowadays, rigid printed circuit boards are usually assembled into receiving bases for electrical application. However, many receiving bases usually have uneven bottoms due to special electrical requirements. Although flexible printed circuit boards adapt suitably to uneven surfaces, the flexible printed circuit boards have poor lifespan and thermal resistance compared to rigid printed circuit boards. However, the flat configuration of rigid printed circuit boards does not adapt well to uneven surfaces.

Therefore, what is needed is a rigid printed circuit board that overcomes the described limitations.

### BRIEF DESCRIPTION OF THE DRAWINGS

Many aspects of the disclosed rigid printed circuit board can be better understood with reference to the following drawings. The components in the drawings are not necessarily drawn to scale, the emphasis instead being placed upon clearly illustrating the principles of the present rigid printed circuit board.

FIG. 1 is a schematic view of a rigid printed circuit board, according to an exemplary embodiment.

FIG. 2 is a schematic view of the rigid printed circuit board in the exemplary embodiment when the connecting portion there of is elastically stretched.

FIG. 3 is a schematic view of the rigid printed circuit board in the exemplary embodiment and a receiving base fit for receiving the rigid printed circuit board.

FIG. 4 is a schematic view the rigid printed circuit board in the exemplary embodiment when assembled into the receiving base of FIG. 3.

### DETAILED DESCRIPTION

Reference will now be made to the drawings to describe the embodiments of the print circuit board, in detail.

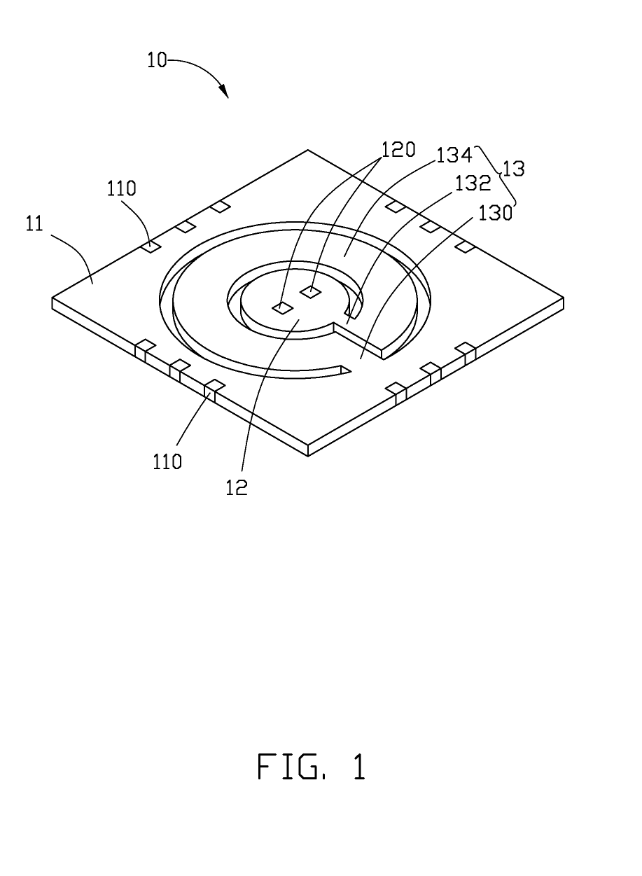

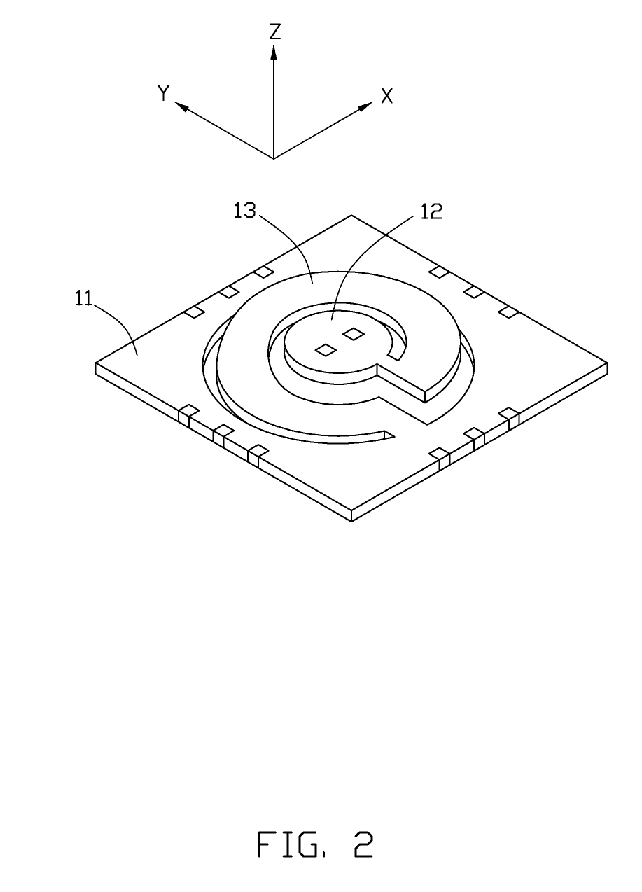

Referring to FIGS. 1 and 2, a print circuit board 10, according to a first embodiment, includes a main portion 11, a supporting portion 12, and a connecting portion 13.

The main portion 11 is rectangular. The main portion 11 has a plurality of electrical contacts 110 along edges thereof.

The supporting portion 12 is generally round. The supporting portion 12 is configured for supporting electrical elements, for example light emitting diodes. The supporting portion 12 has two electrical contacts 120 thereon. The electrical contacts 120 are for providing electrical connection to the electrical elements.

The connecting portion 13 includes a first end portions 130, a second end portions 132, and a main body 134 connected between the first and second end portions 130 and 132. The first end portion 130 is connected to the main portion 11. The second end portion 132 is connected to the supporting portion 12. The main body 134 is located between the main portion 11 and the supporting portion 12, and spaced from the main portion 11 and the supporting portion 12. The connecting portion 13 has an annular shape, the connecting portion 13 surrounds the supporting portion 12, and the main portion 11 surrounds the connecting portion 13. In a still further exemplary embodiment, the main body 134 keeps a predetermined distance apart from the main portion 11 and/or the supporting portion 12. As such, the main body 134 can be more elastic.

The main portion 11, the supporting portion 12, and the connecting portion 13 each has a circuit layer formed in a respective interior thereof. The circuit layers in the main portion 11, the supporting portion 12 and the connecting portion 13 are electrically communicated to each other. The electrical contacts 110 are electrically connected to the circuit layer of the main portion 11. The electrical contacts 120 are electrically connected to the circuit layer of the supporting portion 12. As such, the electrical contacts 120 of the supporting portion 12 are capable of drawing electrical power from the exterior via the electrical contacts 110 of the main portion 11.

As illustrated in FIG. 1, upon a condition that no external force is applied to the supporting portion 12, the supporting portion 12, the main body 134, and the main portion 11 are located in a common plane. As illustrated in FIG. 2, upon a condition that an external force is applied to the supporting portion 12 along a direction (z-direction) perpendicular to the plane, the main body 134 is elastically stretched in a direction perpendicular to the plane, and the supporting portion 12 and the main portion 11 are located in different planes.

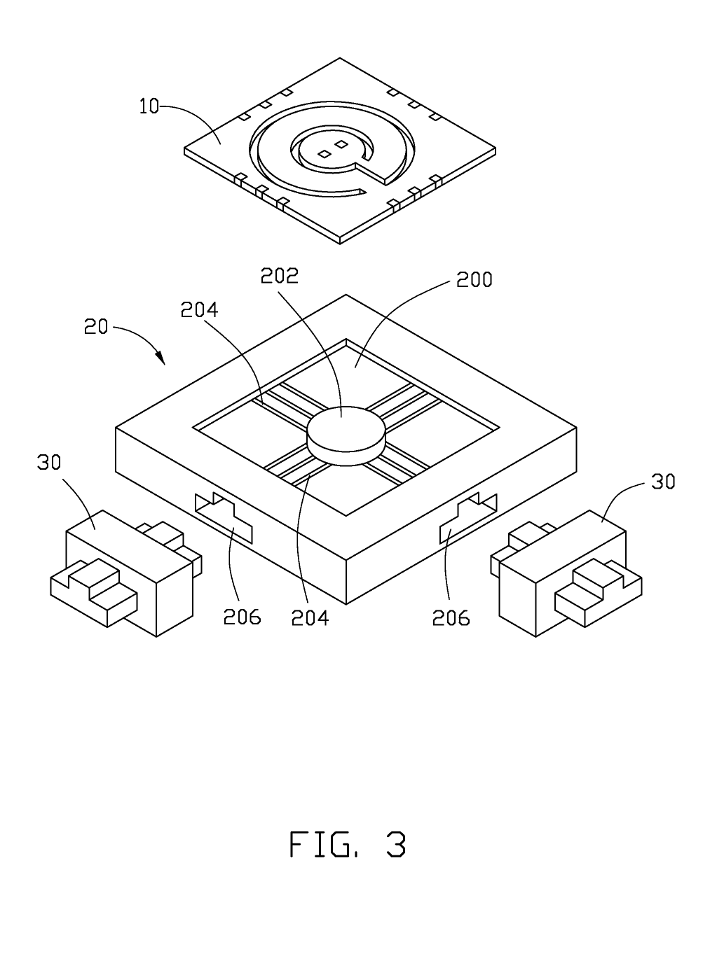

Referring to FIG. 3, a receiving base 20 fit for receiving the printed circuit board 10 is provided. The receiving base 20 includes a receiving space 200, a protrusion 202, and a plurality of electrical contacts 204. The protrusion 202 and the plurality of electrical contacts 204 are arranged at a bottom of the receiving space 200. In an exemplary embodiment, the protrusion 202 has a top surface similar in shape as the bottom surface of the supporting portion 12.

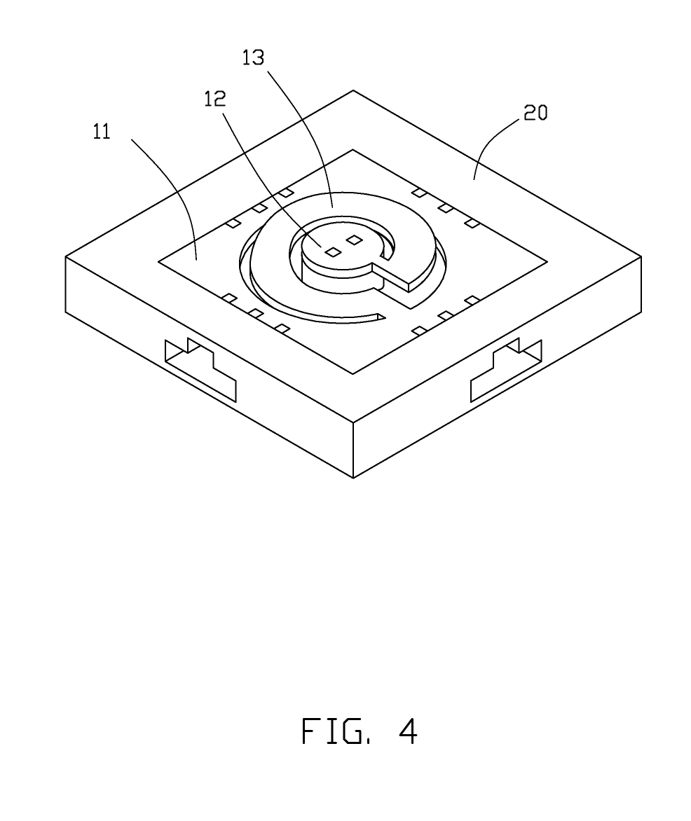

Referring to FIG. 4, the rigid printed circuit board 10 is assembled into the receiving base 20. The main portion 11 is received in the receiving space 200 and located at the bottom thereof. The supporting portion 12 is propped up by the protrusion 202. The connecting portion 13 is elastically stretchable to a position where the connecting portion 13 connects the supporting portion 12 and the main portion 11. In this condition, the electrical contacts 204 are in contact with the electrical contacts 110. As such, the electrical contacts 120 of the supporting portion 12 are capable of drawing electrical power from the exterior via the electrical contacts 204 of the receiving base 20.

In an exemplary embodiment, the supporting portion 12 and the connecting portion 13 is formed by cutting the main portion 11 providing an integral configuration along a spiral line winding around a center of the main portion 11 at a continuously increasing distance from the center. The supporting portion 12 is connected to the main portion 11 only via the connecting portion 13. The main body 134 is capable of being elastically stretched along the z-direction (illustrated in FIG. 2). Therefore, the supporting portion 12 and the main portion 11 can be located in different planes due to the elastic deformation of the main body 134. Accordingly, the rigid printed circuit board 10 can be assembled into a receiving base, for example receiving base 20, having an uneven supporting surface.

It is to be said that, the supporting portion 12 and the connecting portion 13 are not limited to be formed by cutting the integral main portion 11. The main portion 11, the supporting portion 12, and the connecting portion 13 can be originally separate portions, which are then assembled together.

The receiving base 20 can further include at least one socket 206 capable of being coupled to a corresponding connector 30. As such, the receiving base 20 can be connected to another receiving base 20 by the engagement of the sockets 206 and the connectors 30 (as illustrated in FIG. 3). Thereby, a printed circuit board module can be obtained by assembling a plurality of receiving bases 20 under the coupling cooperation of the sockets 206 and the connectors 30.

It is to be said that, the main portion 11 and the supporting portion 12 can also be round, elliptical, triangular or polygonal; the connecting portion 13 can also be circular, elliptical, triangular, or polygonal.

Finally, it is to be understood that the above-described embodiments are intended to illustrate rather than limit the disclosure. Variations may be made to the embodiments without departing from the spirit of the disclosure as claimed. The above-described embodiment illustrates the scope of the disclosure but do not restrict the scope of the disclosure.

What is claimed is:

1. A rigid printed circuit board (PCB), comprising:
a main portion;
a supporting portion for supporting electrical elements;
a connecting portion with two end portions and a main body connected between the two end portions, the main body being located between the main portion and the supporting portion and spaced from the main portion and the supporting portion, the two end portions being respectively connected to the main portion and the supporting portion; wherein the rigid PCB is deformable between a first state in which the supporting portion, the main body, and the main portion are located in a common plane; and a second state in which an external force is applied to the supporting portion along a direction perpendicular to the plane, the main body is elastically stretched in a direction perpendicular to the plane, and the supporting portion and the main portion are located in different planes.

2. The rigid PCB according to claim 1, wherein the main body keeps a predetermined distance apart from the main portion and/or the supporting portion.

3. The rigid PCB according to claim 1, wherein the connecting portion has an annular shape, the connecting portion surrounds the supporting portion, and the main portion surrounds the connecting portion.

4. The rigid PCB according to claim 3, wherein the connecting portion is circular, elliptical, triangular, or polygonal.

5. The rigid PCB according to claim 1, wherein the main portion is round, elliptical, triangular or polygonal.

6. The rigid PCB according to claim 1, wherein the supporting portion is round, elliptical, triangular or polygonal.

7. The rigid PCB according to claim 1, wherein the main portion has a first electrical contact thereon, the supporting portion has a second electrical contact thereon, circuit layers are formed in the interior of the main portion, the supporting portion and the connecting portion, and the first electrical contact is connected to the second electrical contact via the circuit layers.

8. A PCB assembly comprising a rigid PCB and a receiving base:
the rigid PCB comprising
a main portion;
a supporting portion for supporting electrical elements;
a connecting portion with two end portions and a main body connected between the two end portions, the main body being spaced from the main portion and the supporting portion, the two end portions being respectively connected to the main portion and the supporting portion;
the receiving base comprising a receiving space and a protrusion, the protrusion being at a bottom of the receiving space and having a cross section with a shape similar to the supporting portion; wherein
the main portion is received in the receiving space and located at the bottom thereof, the supporting portion is propped up by the protrusion, and the connecting portion is elastically stretchable to a position where the connecting portion connects the supporting portion and the main portion.

9. The PCB assembly according to claim 8, wherein the main portion has a first electrical contact thereon, the supporting portion has a second electrical contact thereon, circuit layers are formed in the interior of the main portion, the supporting portion and the connecting portion, the first electrical contact is connected to the second electrical contact via the circuit layers, the receiving base has a third electrical contact at the bottom of the receiving space, and the third electrical contact is connected to the first electrical contact.

10. A PCB module, comprising a plurality of PCB assemblies of claim 8 and a plurality of connectors, each receiving base of the PCB assemblies has at least one socket coupled to the corresponding connectors, thereby the plurality of PCB assemblies and connectors are connected integrally by the engagement of the sockets with the connectors.
